(19) United States
(12) Patent Application Publication
(10) Pub. No.: US 2015/0143694 A1
(43) Pub. Date: May 28, 2015

(54) CARRIER FOR MANUFACTURING PRINTED CIRCUIT BOARD AND MANUFACTURING METHOD THEREOF, AND METHOD FOR MANUFACTURING PRINTED CIRCUIT BOARD

(71) Applicant: Samsung Electro-Mechanics Co., Ltd., Suwon (KR)

(72) Inventors: Jae Ean Lee, Busan (KR); Jung Hyun Cho, Suwon (KR); Kyung Hwan Ko, Yeongi (KR); Yong Ho Baek, Seoul (KR)

(73) Assignee: Samsung Electro-Mechanics Co., Ltd., Suwon (KR)

(21) Appl. No.: 14/486,535

(22) Filed: Sep. 15, 2014

(30) Foreign Application Priority Data
Nov. 25, 2013 (KR) 10-2013-0143850

(51) Int. Cl. H05K 3/10

(52) U.S. Cl. CPC H05K 3/10; H05K 2203/0228
USPC 29/846; 269/289 R

(57) ABSTRACT

Disclosed herein is a carrier for manufacturing a printed circuit board, including: an insulating layer; a release layer buried in at least any one of top and bottom surfaces of the insulating layer and having a length shorter than that of the insulating layer; and a metal foil bonded to a surface of the insulating layer in which the release layer is buried and having a length longer than that of the release layer, thereby increasing reliability of a product in the manufacturing the substrate using the carrier.

### CROSS REFERENCE(S) TO RELATED APPLICATIONS

This application claims the benefit under 35 U.S.C. Section 119 of Korean Patent Application Serial No. 10-2013-0143850, entitled “Carrier For Manufacturing Printed Circuit Board And Manufacturing Method Thereof, And Method For Manufacturing Printed Circuit Board” filed on Nov. 25, 2013, which is hereby incorporated by reference in its entirety into this application.

### BACKGROUND OF THE INVENTION

1. Technical Field

The present invention relates to a printed circuit board, and more particularly, to a carrier for manufacturing a printed circuit board.

2. Description of the Related Art

Generally, a printed circuit board (PCB) is a component in which a copper foil is wired on one surface or both surfaces of the board made of various synthetic resins, an IC or electronic components are mounted on the board, and an electrical wiring between the electronic components is implemented. Recently, with the trend of electronic devices toward high performance and miniaturization, a multilayer printed circuit board has been produced as a board for mounting electronic components at a high density.

The multilayer printed circuit board is formed by using as a core layer a reinforcing material in which a glass fiber, and the like is impregnated in a resin composition and alternately stacking an insulating layer and a wiring layer on both surfaces of the core layer by a build up process. Since the wiring layer is finely formed, the multilayer printed circuit board may be mounted with electronic components at a high density.

However, since it is difficult to implement fineness of a through hole penetrating through the core layer, a coreless substrate which does not have the core layer is drawing attention recently.

In the case of the coreless substrate, since the core layer is not used, the use of a carrier member serving as a support during the manufacturing process is required. That is, the substrate may be finally completed by repeatedly stacking the insulating layer and the wiring layer on both surfaces of the carrier and then separating a laminate from the carrier.

Even though various types of carrier members are present, the carrier member generally has a structure in which a first metal plate and a second metal plate are stacked on the insulating layer, having a release layer disposed therebetween. The substrate is formed by using the carrier member as the support and then the carrier is separated from the substrate by the release layer.

However, since the carrier member has a structure in which the release layer is exposed to the outside, the exposed release layer may crack due to an externally physical impact, permeation of medicines, and the like during the manufacturing process of the substrate.

As the method for solving the problem, Japanese Patent Laid-Open Publication No. 2013-162124 discloses a structure in which an outside of the carrier is enclosed with a protective means of a resin composition. However, in this case, the manufacturing process may be ineffective due to the addition of separate components and costs may be increased. Further, the protective means is made of the resin composition, and thus is expected to be vulnerable to substrate warpage characteristics.

### SUMMARY OF THE INVENTION

An object of the present invention is to protect a release layer from the outside by using a carrier having a structure in which a release layer is buried in a surface of an insulating layer and increase reliability of a product.

According to an exemplary embodiment of the present invention, there is provided a carrier for manufacturing a printed circuit board, including: an insulating layer; a release layer buried in at least any one of top and bottom surfaces of the insulating layer and having a length shorter than that of the insulating layer; and a metal foil bonded to a surface of the insulating layer in which the release layer is buried and having a length longer than that of the release layer.

The release layer may be buried, having margin parts from both side ends of the insulating layer.

A length of the metal foil may be equal to that of the insulating layer.

The release layer may be made of a metal material.

The release layer may be made of metal of a material different from the metal foil.

A thickness of the release layer may be changed depending on a weight of a wiring layer which is stacked over the insulating layer.

The release layer may be configured of a first release layer which is buried in the insulating layer and a second release layer which is buried in the other surface of the first release layer, and a weight of the wiring layer which is stacked on one surface of the insulating layer including the first release layer and a weight of the wiring layer which is stacked on the other surface of the insulating layer including the second release layer may be symmetrical to each other.

According to another exemplary embodiment of the present invention, there is provided a manufacturing method of a carrier for manufacturing a printed circuit board, including: preparing an insulating layer; burying a release layer having a length shorter than that of the insulating layer in at least any one of top and bottom surfaces of the insulating layer; and bonding a metal foil having a length longer than that of the release layer to a surface of the insulating layer in which the release layer is buried.

In the burying of the release layer, the burying layer may be buried, having margin parts from both side ends of the insulating layer.

In the bonding of the metal foil in the surface of the insulating layer in which the release layer is buried, the metal foil may be bonded so that the release layer and the metal foil are vacuum compressed.

According to still another exemplary embodiment of the present invention, there is provided a method for manufacturing a printed circuit board using the carrier for manufacturing a printed circuit board as described above, including: forming a substrate on the carrier for manufacturing a printed circuit board on which the metal foil is formed; cutting an edge of the carrier for manufacturing a printed circuit board including the substrate in a thickness direction so that the release layer is exposed; and separating the substrate from the carrier for manufacturing a printed circuit board.

In the cutting of the edge of the carrier for manufacturing a printed circuit board in a thickness direction, the edge may be cut along an edge line of the release layer.

### BRIEF DESCRIPTION OF THE DRAWINGS

FIG. 1 is a cross-sectional view of a carrier for manufacturing a printed circuit board according to an exemplary embodiment of the present invention.

FIGS. 2 to 4 are process diagrams sequentially illustrating a manufacturing method of a carrier for manufacturing a printed circuit board according to the exemplary embodiment of the present invention.

FIGS. 5 to 7 are process diagrams sequentially illustrating a method of manufacturing a printed circuit board using the carrier for manufacturing a printed circuit board according to the exemplary embodiment of the present invention.

FIG. 8 is a diagram for describing another exemplary embodiment of FIG. 6.

### DESCRIPTION OF THE PREFERRED EMBODIMENTS

Various advantages and features of the present invention and methods accomplishing thereof will become apparent from the following description of exemplary embodiments with reference to the accompanying drawings. However, the present invention may be modified in many different forms and it should not be limited to exemplary embodiments set forth herein. These exemplary embodiments may be provided so that this disclosure will be thorough and complete, and will fully convey the scope of the invention to those skilled in the art.

In addition, terms used in the present specification are for explaining the embodiments rather than limiting the present invention. Unless explicitly described to the contrary, a singular form includes a plural form in the present specification. The word “comprise” and variations such as “comprises” or “comprising,” will be understood to imply the inclusion of stated constituents, steps, operations and/or elements but not the exclusion of any other constituents, steps, operations and/or elements.

Hereinafter, a configuration and an acting effect of exemplary embodiments of the present invention will be described in more detail with reference to the accompanying drawings.

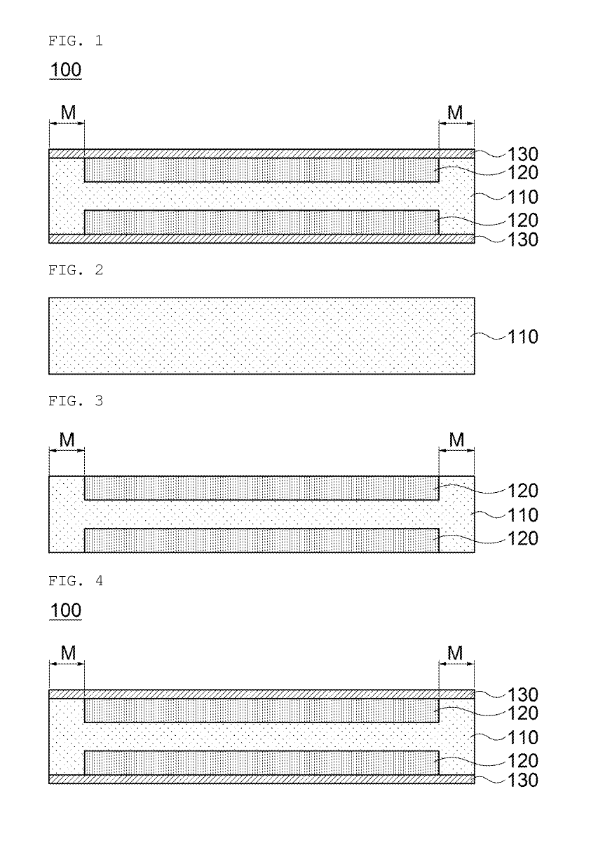

FIG. 1 is a cross-sectional view of a carrier for manufacturing a printed circuit board according to an exemplary embodiment of the present invention. Additionally, components shown in the accompanying drawings are not necessarily shown to scale. For example, sizes of some components shown in the accompanying drawings may be exaggerated as compared with other components in order to assist in the understanding of the exemplary embodiments of the present invention. Meanwhile, throughout the accompanying drawings, the same reference numerals will be used to describe the same components. For simplification and clearness of illustration, a general configuration scheme will be shown in the accompanying drawings, and a detailed description of the feature and the technology well known in the art will be omitted in order to prevent a discussion of exemplary embodiments of the present invention from being unnecessarily obscure.

Referring to FIG. 1, a carrier 100 for manufacturing a printed circuit board according to an exemplary embodiment of the present invention has an insulating layer 110, a release layer 120, and a metal foil 130 as basic components.

A resin material of the insulating layer 110 may be appropriately selected in consideration of insulating property, heat resistance, moisture resistance, and the like. For example, as an optimal polymer material forming the insulating layer 110, an epoxy resin, a phenol resin, a urethane resin, a silicon resin, a polyimide resin, and the like may be used and to increase a mechanical strength of a support, a prepreg in which reinforcing materials, such as a glass fiber and an inorganic filler, are impregnated may also be used.

The release layer 120 may be provided in the state buried in the surface of the insulating layer 110. That is, when the release layer 120 is a rectangular flat plate which has an upper surface, a lower surface opposite thereto, and a side having a predetermined thickness, the release layer 120 is buried in a form in which the upper surface is exposed to the outside and the lower surface and the side are enclosed with a resin. The term ‘burying’ indicates one buried in the above form.

The release layer 120 may be buried in any one of the upper and lower surfaces of the insulating layer 110 or may be buried in both surfaces thereof. However, the present invention illustrates, as the example, the case in which the release layers 120 are buried in both surfaces of the insulating layer 110 to manufacture the coreless substrate.

Herein, the length of the release layer 120 may be smaller than that of the insulating layer 110. Therefore, the release layers 120 may be buried, having predetermined margin parts M from both side ends of the insulating layer 110.

Since the margin part M is a region discarded after a cutting process in the method for manufacturing a printed circuit board using the carrier 100, an interval of the margin part M may be set to be smaller to extend a real area of the substrate. However, when the margin part M is set to be too small, a bonded portion with the metal foil 130 is reduced to make the structure instable. Therefore, the interval of the margin part M may be set to have an appropriate length in consideration of the relationship therebetween.

The metal foil 130 may be provided while being bonded with the surface of the insulating layer 110 in which the release layer 120 is buried. Therefore, according to the exemplary embodiment of the present invention in which the release layers 120 are buried in both surfaces of the insulating layer 110, the metal foils 130 may be provided on both surfaces of the insulating layer 110 as illustrated in FIG. 1.

The metal foil 130 may be used as a wiring layer of the substrate separated from the carrier 100. Therefore, as a construction material of the metal foil 130, copper (Cu), nickel (Ni), aluminum (Al), or the like may be used, but the exemplary embodiment of the present invention is not limited thereto.

A length of the metal foil 130 may be formed to be larger than that of the release layer 120, such that the metal foil 130 is bonded to the insulating layer 110 made of an adhesive resin composition in the margin part M region. Therefore, to extend the bonded area to the insulating layer 110, the length of the metal foil 130 may be formed to be equal to that of the insulating layer 110.

Generally, in the carrier for manufacturing a printed circuit board, the release layer is made of adhesive materials such as a polymer material, for example, fluorines, silicons, polyethylene terephthalates, polymethyl pentene, and the like so as to being bonded to metal. However, according to the exemplary embodiment of the present invention, the release layer 120 is made of a metal material. For example, the release layer 120 may be made of a metal selected from gold (Au), silver (Ag), iron (Fe), titanium (Ti), tin (Sn), nickel (Ni), and molybdenum (Mo). However, to prevent the chemical bonding by the same kind of materials, the metal materials different from the metal foil 130 may be used.

As such, as the release layer 120 is made of the metal materials, the release layer 120 is not bonded to the metal foil 130, and then even though the substrate is separated from the carrier 100 in a method for manufacturing a printed circuit board using the carrier 100 according to the exemplary embodiment of the present invention, separate foreign materials do not remain on the surface of the metal foil 130 which becomes the wiring layer of the substrate.

Meanwhile, a thickness of the release layer 120 may be changed depending on a weight of the wiring layers which are stacked on the insulating layer 110 in the method for manufacturing a printed circuit board using the carrier 100 according to the exemplary embodiment of the present invention.

Generally, at the time of manufacturing the substrate, when heat is applied during a reflow process, the insulating layer 110 made of a high expansive resin is expanded and contracted, such that warpage occurs. A substrate is further warped to a heavier side when an interlayer metal occupancy factor by the wiring layer, that is, a weight is asymmetrical. Therefore, according to the exemplary embodiment of the present invention, for example, when the weight of the wiring layer disposed on the upper portion among the multilayer wiring layers which are stacked on the insulating layer 110 is larger than the wiring layer disposed on the lower portion, the thickness of the release layer 120 is larger and thus the metal weight of the lower portion is increased, such that the warpage of the substrate may be induced to the lower portion.

Meanwhile, when a total weight of the wiring layer which is stacked on the insulating layer 110 based on the insulating layer 110 is different from that of the wiring layer which is stacked on the lower portion of the insulating layer 110, the wiring layer is further expanded to a side at which the total weight of the wiring layer is larger. Therefore, in this case, the metal weight of the upper and lower portions of the insulating layer 110 may be symmetrical with each other by controlling the thickness of the release layer 120 which is buried in one surface of the insulating layer 110 and the thickness of the release layer 120 which is buried in the other surface thereof.

For example, in the case in which the total weight of the wiring layer on the upper portion of the insulating layer 110 based on the insulating layer 110 is larger than that of the wiring layer on the lower portion of the insulating layer 110, when the release layer 120 buried in the upper portion of the insulating layer 110 is called a first release layer and the release layer 120 buried in the lower surface of the insulating layer 110 is called a second release layer, the thickness of the second release layer may be larger than that of the first release layer. As a result, the total weight of the wiring layer on the upper portion of the insulating layer 110 including the first release layer and the total weight of the wiring layer on the lower portion of the insulating layer 110 including the second release layer are symmetrical to each other, such that the substrate warpage phenomenon may be improved.

As such, when the release layer 120 is made of a metal material, foreign matters do not remain on the surface of the metal foil 130 after the substrate is separated, such that process defects may be reduced and the substrate warpage phenomenon may be improved.

Hereinafter, a method for manufacturing the carrier 100 for manufacturing a printed circuit board according to the exemplary embodiment of the present invention will be described.

FIGS. 2 to 4 are process diagrams sequentially illustrating a manufacturing method of a carrier 100 for manufacturing a printed circuit board according to the exemplary embodiment of the present invention. First, as illustrated in FIG. 2, the insulating layer 110 is prepared.

As the insulating layer 110, a thermosetting resin such as epoxy resin and a thermoplastic resin such as polyimide may be used. Further, to increase a mechanical strength of the support, a prepreg in which reinforcing materials, such as a glass fiber and an inorganic filler, are impregnated in a polymer resin may also be used. Herein, to bury the release layer 120 in the surface of the insulating layer 110, it is important to prepare the insulating layer 110 in a semi-hardening state.

Next, as illustrated in FIG. 3, burying the releasing layer 120 in at least any one of the upper and lower surfaces of the insulating layer 110 is performed.

A metal thin plate may be used as the release layer 120. In this case, an outside of the prepared metal thin plate is removed by mechanical polishing or chemical polishing to be manufactured in a form having a shorter length than the insulating layer 110. For example, the mechanical polishing may be performed by using any one of belt sander, grinder, and a sand blaster and the chemical polishing may be performed by using an etchant, but the exemplary embodiment of the present invention is not limited thereto.

By doing so, when the release layer 120 is manufactured, the release layer 120 is provisionally bonded to the surface of the insulating layer 110, having the predetermined margin parts M from both side ends of the insulating layer 110, and then a force is applied in a stacking direction to bury the release layer 120 in the surface of the insulating layer 110.

Next, as illustrated in FIG. 4, a process of bonding the metal foil 130 to the surface of the insulating layer 110 in which the release layer 120 is buried proceeds.

The length of the metal foil 130 is larger than that of the release layer 120 (equal to the length of the insulating layer 110 in a more preferable form) and since the insulating layer 110 has adhesion in a semi-hardening state, the metal foil 130 is bonded to the insulating layer 110 in the margin part M region. Further, as the release layer 120 is made of a metal material, the metal foil 130 and the release layer 120 are compressed in a vacuum state without being bonded to each other.

Hereinafter, a method of manufacturing a printed circuit board by using the carrier 100 for manufacturing a printed circuit board which is completed according to the exemplary embodiment of the present invention will be described.

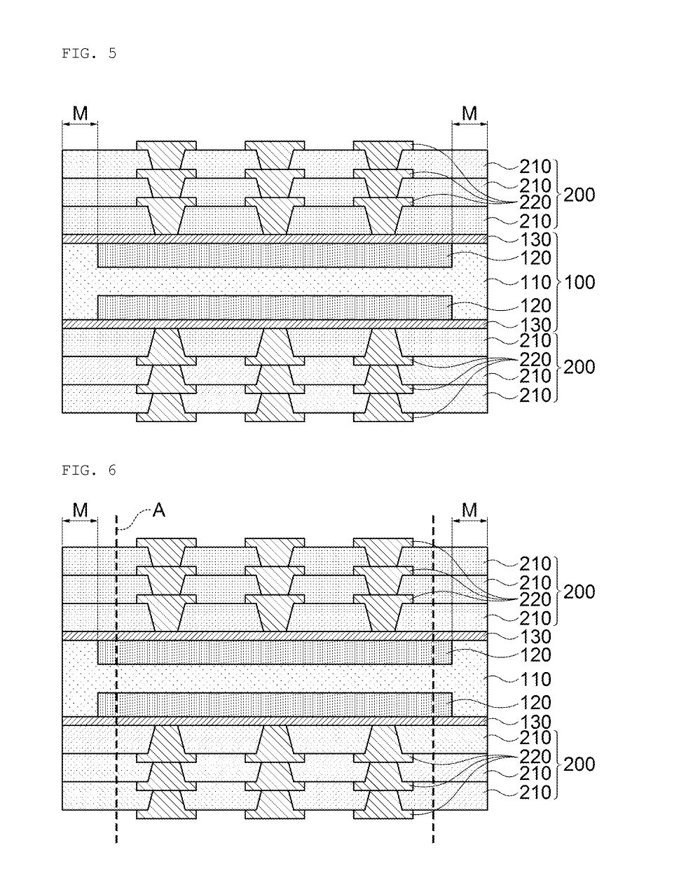

FIGS. 5 to 7 are process diagrams sequentially illustrating the method for manufacturing a printed circuit board using the carrier 100 for manufacturing a printed circuit board according to the exemplary embodiment of the present invention. First, as illustrated in FIG. 5, a process of forming the substrate 200 on the prepared carrier 100 for manufacturing a printed circuit board proceeds.

In more detail, in the carrier 100, the substrate 200 may be stacked on a surface on which the metal foil 130 is formed. Since the exemplary embodiment of the present invention discloses the carrier 100 in which the metal foils 130 are disposed on both surfaces of the insulating layer 110, FIGS. 5 to 7 illustrate that the substrates 200 are on both of the upper and lower surfaces of the carrier 100.

The substrate 200 is formed by a build up process of repeatedly stacking a build up insulating layer 210 and a wiring layer 220. The substrate 200 may be formed by performing a putter operation, pattern formation, hole machining, a plating process, an etching process, and the like, in particular, the wiring layer 220 may be formed by a general semi-additive process (SAP), modified semi-additive process (MSAP), subtractive method, and the like which are known to those skilled in the art. The method of forming the substrate 200 is already known to those skilled in the art, and therefore the detailed description thereof will be omitted.

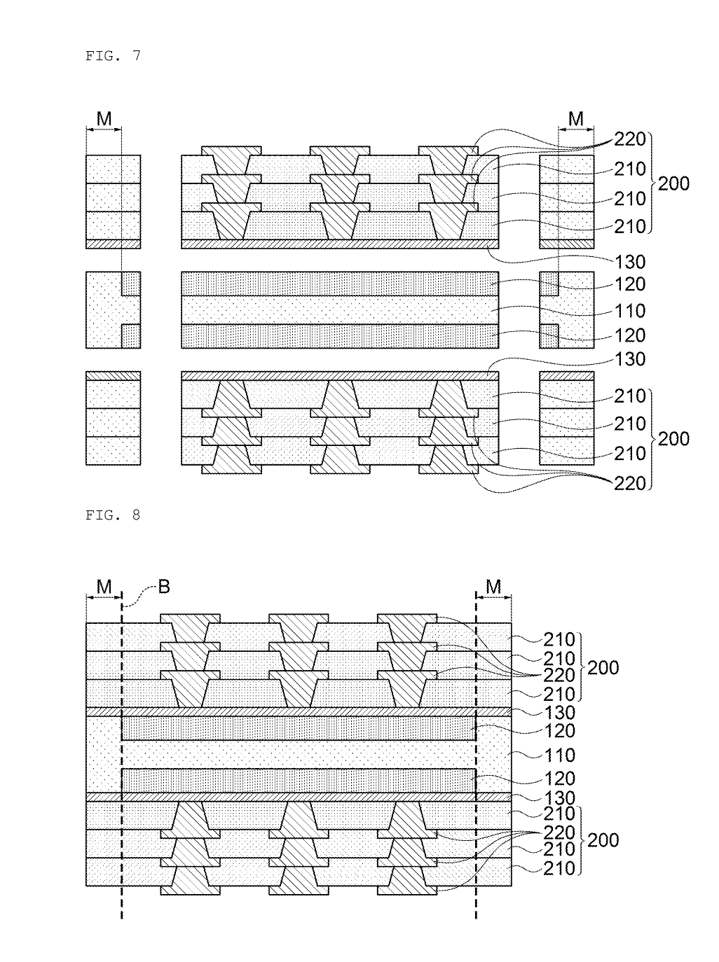

Next, as illustrated in FIG. 6, a process of cutting an edge of the carrier 100 for manufacturing a printed circuit board including the substrate 200 in a thickness direction proceeds.

This may proceed by a routing process. In this case, the edge of the carrier 100 is cut along a cutting line A illustrated in FIG. 6 so that the release layer 120 is exposed. However, when the edge of the carrier 100 is cut along a cutting line A, a part of the release layer 120 is cut, which leads to the reduction in the area of the substrate. As illustrated in FIG. 8, it may be preferable to cut the edge of the carrier 100 along a cutting line B so as to coincide with an edge line of the release layer 120.

As such, when the edge of the carrier 100 is cut along the cutting line A or the cutting line B, as illustrated in FIG. 7, the margin part M which is the bonded portion between the metal foil 130 and the insulating layer 110 is separated and the substrate 200 may be separated from the carrier 100 while supplying air between the release layer 120 and the metal foil 130 which are vacuum compressed.

As described above, in the case of using the carrier 100 for manufacturing a printed circuit board according to the exemplary embodiment of the present invention, the release layer 120 is buried in the surface of the insulating layer 110 and provided in a form sealed with the metal foil 130, and thus may protect the release layer 120 from the externally physical impact or the permeation of medicines until the above-mentioned process of manufacturing the substrate is completed.

In the case of using the carrier for manufacturing a printed circuit board according to the exemplary embodiments of the present invention, the release layer is buried on the surface of the insulating layer and is provided in a form sealed with the metal foil, thereby protecting the release layer from the externally physical impact or the permeation of medicines until the manufacturing process of the substrate is completed.

Further, even though the substrate is separated from the carrier, it is possible to prevent the separate foreign matters from remaining on the surface of the metal foil which is the wiring layer of the substrate.

In addition, it is possible to improve the substrate warpage phenomenon by controlling the thickness of the release layer depending on the weight of the wiring layer stacked over the carrier.

The present invention has been described in connection with what is presently considered to be practical exemplary embodiments. Although the exemplary embodiments of the present invention have been described, the present invention may be also used in various other combinations, modifications and environments. In other words, the present invention may be changed or modified within the range of concept of the invention disclosed in the specification, the range equivalent to the disclosure and/or the range of the technology or knowledge in the field to which the present invention pertains. The exemplary embodiments described above have been provided to explain the best state in carrying out the present invention. Therefore, they may be carried out in other states known to the field to which the present invention pertains in using other inventions such as the present invention and also be modified in various forms required in specific application fields and usages of the invention. Therefore, it is to be understood that the invention is not limited to the disclosed embodiments. It is to be understood that other embodiments are also included within the spirit and scope of the appended claims.

1. A carrier for manufacturing a printed circuit board, comprising:
an insulating layer;
a release layer buried in at least any one of top and bottom surfaces of the insulating layer and having a length shorter than that of the insulating layer; and
a metal foil bonded to a surface of the insulating layer in which the release layer is buried and having a length longer than that of the release layer.

2. The carrier according to claim 1, wherein the release layer is buried, having margin parts from both side ends of the insulating layer.

3. The carrier according to claim 1, wherein a length of the metal foil is equal to that of the insulating layer.

4. The carrier according to claim 1, wherein the release layer is made of a metal material.

5. The carrier according to claim 1, wherein the release layer is made of metal of a material different from the metal foil.

6. The carrier according to claim 1, wherein a thickness of the release layer is changed depending on a weight of a wiring layer which is stacked on the insulating layer.

7. The carrier according to claim 1, wherein the release layer is configured of a first release layer which is buried in the insulating layer and a second release layer which is buried in the other surface of the first release layer, and
a weight of the wiring layer which is stacked on one surface of the insulating layer including the first release layer and a weight of the wiring layer which is stacked on the other surface of the insulating layer including the second release layer are symmetrical to each other.

8. A manufacturing method of a carrier for manufacturing a printed circuit board, comprising:
preparing an insulating layer;
burying a release layer having a length shorter than that of the insulating layer in at least any one of top and bottom surfaces of the insulating layer; and
bonding a metal foil having a length longer than that of the release layer to a surface of the insulating layer in which the release layer is buried.

9. The manufacturing method according to claim 8, wherein in the burying of the release layer, the burying layer is buried, having margin parts from both side ends of the insulating layer.

10. The manufacturing method according to claim 8, wherein in the bonding of the metal foil in the surface of the insulating layer in which the release layer is buried, the metal foil is bonded so that the release layer and the metal foil are vacuum compressed.

11. A method for manufacturing a printed circuit board using the carrier for manufacturing a printed circuit board according to claim 1, comprising:
forming a substrate on the carrier for manufacturing a printed circuit board on which the metal foil is formed;
cutting an edge of the carrier for manufacturing a printed circuit board including the substrate in a thickness direction so that the release layer is exposed; and
separating the substrate from the carrier for manufacturing a printed circuit board.

12. The manufacturing method according to claim 11, wherein in the cutting of the edge of the carrier for manufacturing a printed circuit board in a thickness direction, the edge is cut along an edge line of the release layer.

13. A method for manufacturing a printed circuit board using the carrier for manufacturing a printed circuit board according to claim 2, comprising:
forming a substrate on the carrier for manufacturing a printed circuit board on which the metal foil is formed;
cutting an edge of the carrier for manufacturing a printed circuit board including the substrate in a thickness direction so that the release layer is exposed; and
separating the substrate from the carrier for manufacturing a printed circuit board.

14. A method for manufacturing a printed circuit board using the carrier for manufacturing a printed circuit board according to claim 3, comprising:
forming a substrate on the carrier for manufacturing a printed circuit board on which the metal foil is formed;
cutting an edge of the carrier for manufacturing a printed circuit board including the substrate in a thickness direction so that the release layer is exposed; and
separating the substrate from the carrier for manufacturing a printed circuit board.

15. A method for manufacturing a printed circuit board using the carrier for manufacturing a printed circuit board according to claim 4, comprising:
forming a substrate on the carrier for manufacturing a printed circuit board on which the metal foil is formed;
cutting an edge of the carrier for manufacturing a printed circuit board including the substrate in a thickness direction so that the release layer is exposed; and
separating the substrate from the carrier for manufacturing a printed circuit board.

16. A method for manufacturing a printed circuit board using the carrier for manufacturing a printed circuit board according to claim 5, comprising:
forming a substrate on the carrier for manufacturing a printed circuit board on which the metal foil is formed;
cutting an edge of the carrier for manufacturing a printed circuit board including the substrate in a thickness direction so that the release layer is exposed; and
separating the substrate from the carrier for manufacturing a printed circuit board.

17. A method for manufacturing a printed circuit board using the carrier for manufacturing a printed circuit board according to claim 6, comprising:
forming a substrate on the carrier for manufacturing a printed circuit board on which the metal foil is formed;
cutting an edge of the carrier for manufacturing a printed circuit board including the substrate in a thickness direction so that the release layer is exposed; and
separating the substrate from the carrier for manufacturing a printed circuit board.

18. A method for manufacturing a printed circuit board using the carrier for manufacturing a printed circuit board according to claim 7, comprising:
forming a substrate on the carrier for manufacturing a printed circuit board on which the metal foil is formed;
cutting an edge of the carrier for manufacturing a printed circuit board including the substrate in a thickness direction so that the release layer is exposed; and
separating the substrate from the carrier for manufacturing a printed circuit board.
